(19) United States
(12) Patent Application Publication
(10) Pub. No.: US 2025/0255122 A1
(43) Pub. Date: Aug. 7, 2025

(54) Display Apparatus

(71) Applicant: LG Display Co., Ltd., Seoul (KR)

(72) Inventor: Yonghee Jo, Paju-si (KR)

(21) Appl. No.: 18/902,274

(22) Filed: Sep. 30, 2024

(30) Foreign Application Priority Data
Feb. 5, 2024 (KR) 10-2024-0017381

(51) Int. Cl. H10K 59/131; H10K 59/122; H10K 59/35

(52) U.S. Cl. CPC H10K 59/131; H10K 59/122; H10K 59/351

(57) ABSTRACT

The present disclosure provides a display device including a substrate including a display area allowing an image to be displayed and a non-display area outside of the display area, a first protective layer over the substrate, a second protective layer disposed on the first protective layer and having a first opening, a plurality of first electrodes disposed on the second protective layer, and a wall pattern disposed on the first protective layer and located at an boundary or inside of the first opening.

### CROSS-REFERENCE TO RELATED APPLICATIONS

This application claims the priority benefit of Republic of Korea Patent Application No. 10-2024-0017381, filed on Feb. 5, 2024, in the Korean Intellectual Property Office, which is incorporated herein by reference for all purposes as if fully set forth herein.

### TECHNICAL FIELD

The present disclosure relates to electronic devices with displays, and more specifically, to a display device.

### BACKGROUND

As the information-oriented society has been developed, various needs for display devices (which may be referred to as displays) for displaying an image have increased. As such displays, liquid crystal displays (LCD), inorganic light emitting displays, organic light emitting diode (OLED) displays, quantum dot (QD) displays, and the like have been developed and increasingly used.

Among these displays, organic light emitting diode (OLED) displays have a self-emitting property, and can provide advantages of a wider viewing angle, a higher contrast ratios, and the like compared to liquid crystal displays (LCD). The OLED displays can be packaged with a thinner thickness and a lighter weight without the need for a backlight, and consume much less power. In addition, the organic light emitting diode (OLED) display can be driven at low direct current voltages, have a fast response time, and in particular, be manufactured at low costs.

### SUMMARY

One or more aspects of the present disclosure may provide a display device capable of reducing or minimizing leakage current.

One or more aspects of the present disclosure may provide a display device capable of address an issue where a deposited material does not have a uniform thickness depending on relative locations of a deposition source and a unit display panel during a deposition process.

One or more aspects of the present disclosure may provide a display device capable of preventing one or more subpixels not driven for image displaying among a plurality of subpixels having a common intermediate layer and a cathode layer from emitting light due to lateral leakage current (herein, the term “lateral leakage current” may refer to leakage current flowing along a boundary or a portion of an opening formed in a subpixel).

One or more aspects of the present disclosure may provide a display device capable of improving color gamut and display quality in a low grayscale by preventing one or more unintended subpixels from emitting light.

Problems or issues to be solved herein are not limited to the above description, and other problems or issues to be solved will become apparent to those skilled in the art from the following description.

According to one or more example embodiments of the present disclosure, a display device can be provided that includes a substrate including a display area allowing an image to be displayed and a non-display area outside of the display area, a first protective layer over the substrate, a second protective layer disposed on the first protective layer and having a first opening, a plurality of first electrodes disposed on the second protective layer, and a wall pattern disposed on the first protective layer and located at an boundary or inside of the first opening.

According to one or more embodiments of the present disclosure, a display device includes a substrate, a first protective layer on the substrate, a second protective layer on the first protective layer, the second protective layer including a part and another part, wherein at least a portion of the first protective layer is exposed between the part and the another part of the second protective layer, a first subpixel and a second subpixel on the substrate, wherein a light emitting element of the first subpixel is disposed on the part of the second protective layer and a light emitting element of the second subpixel is disposed on the another part of the second protective layer, and a wall pattern disposed on the first protective layer, wherein at least a portion of the wall pattern is covered by the second protective layer or is disposed on the exposed portion of the first protective layer.

According to one or more aspects of the present disclosure, a display device may be provided that enables an emission layer or a cathode layer to be deposited in a display panel with a uniform thickness regardless of locations during a deposition process by disposing a wall pattern considering relative locations of a deposition source and a display panel.

According to one or more aspects of the present disclosure, a display device may be provided that, by disposing a wall pattern, is capable of preventing the penetration of oxygen into, and the shrinkage of, a light emitting element (or one or more elements included in the light emitting element) due to a reduction in a thickness at which an emission layer or a cathode layer is deposited, or a disconnection of the emission layer or the cathode layer.

According to one or more aspects of the present disclosure, a display device may be provided that is configured with a structure where an opening is formed in a portion of protective layer located in an area between adjacent subpixels, and a wall pattern is disposed at an boundary or inside of the opening of the protective layer, and provides an advantage of reducing lateral leakage current by enabling current flowing through a common intermediate layer to be discharged through the wall pattern as a ground voltage is applied to the wall pattern.

According to one or more aspects of the present disclosure, a display device may be provided that is capable of improving color gamut by minimizing unintended emission of one or more light emitting elements through a reduction of lateral leakage current, and improving display quality by minimizing display artifacts, such as luminance disparities, color differences, and the like, which may be visible while images with low grayscales are displayed.

Additional features and aspects will be set forth in part in the description which follows and in part will become apparent from the description or may be learned by practice of the inventive concepts provided herein. Other features and aspects of the inventive concepts may be realized and attained by the structure particularly pointed out in, or derivable from, the written description, the claims hereof, and the appended drawings. Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the appended claims. Nothing in this section should be taken as a limitation on those claims.

It is to be understood that both the foregoing general description and the following detailed description of the present disclosure are exemplary and explanatory and are intended to provide further explanation of the inventive concepts as claimed.

### BRIEF DESCRIPTION OF THE DRAWINGS

FIG. 1 schematically illustrates the configuration of an example display device according to aspects of the present disclosure.

FIG. 2 illustrates an example configuration of a display panel according to aspects of the present disclosure.

FIG. 3 is an example plan view schematically illustrating a deposition process for forming light emitting elements according to aspects of the present disclosure.

FIG. 4 is an example cross-sectional view illustrating the result of performing a deposition process on a substrate according to aspects of the present disclosure.

FIG. 5 is an example cross-sectional view illustrating lateral leakage current sourced from a common intermediate layer according to aspects of the present disclosure.

FIG. 6 illustrates an example where lateral leakage current is discharged through a wall pattern in the display device according to aspects of the present disclosure.

FIGS. 7A to 7D illustrate example cross-sections of the display panel including a respective wall pattern according to aspects of the present disclosure.

FIGS. 8A to 8D illustrate example cross-sections of the display panel including a respective wall pattern according to aspects of the present disclosure.

FIG. 9 is an example plan view illustrating that a display area is divided into sub-areas in different locations in the display panel according to aspects of the present disclosure.

FIG. 10A is a cross-sectional view illustrating example locations of wall patterns disposed in the display area in Case 1 in the display panel according to aspects of the present disclosure.

FIG. 10B is a cross-sectional view illustrating example locations of wall patterns disposed in the display area in Case 2 in the display panel according to aspects of the present disclosure.

FIG. 10C is a cross-sectional view illustrating example locations of wall patterns disposed in the display area in Case 3 in the display panel according to aspects of the present disclosure.

FIGS. 11A to 11C illustrate example wall patterns disposed between subpixels in the display panel according to aspects of the present disclosure.

### DETAILED DESCRIPTION

Reference will now be made in detail to embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various example embodiments of the present disclosure will be described in detail.

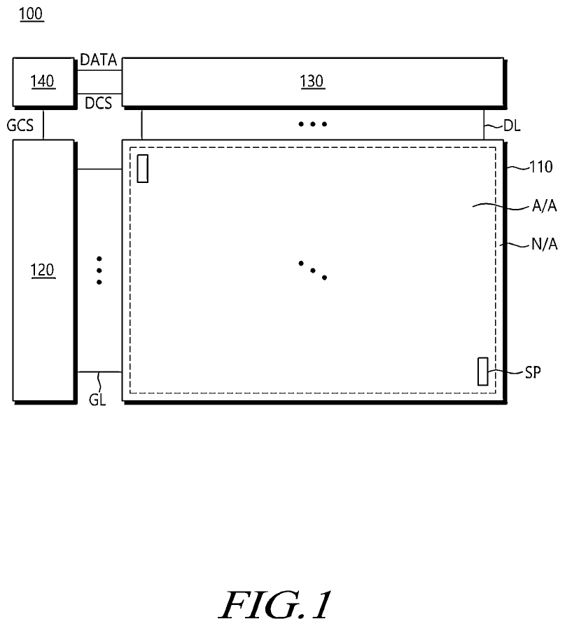

FIG. 1 schematically illustrates the configuration of an example display device 100 according to aspects of the present disclosure.

Referring to FIG. 1, in one or more example embodiments, the display device 100 may include a display panel 110 including a display area A/A allowing a plurality of subpixels SP to be disposed and a non-display area N/A located outside of the display area A/A. The display device 100 may include a gate driving circuit 120, a data driving circuit 130, a controller 140, and the like, for driving several types of signal lines disposed in display panel 110.

A plurality of gate lines GL and a plurality of data lines DL may be disposed in the display panel 110, and a respective one of the plurality of subpixel SP may be disposed in each area where the gate lines GL and the data lines DL intersect each other.

The gate driving circuit 120 can be controlled by the controller 140, and can control driving timings of the plurality of subpixel SP by sequentially outputting scan signals to the plurality of gate lines GL disposed in display panel 110.

The gate driving circuit 120 may include one or more gate driver integrated circuits GDIC. The gate driving circuit 120 may be located in, and/or electrically connected to, but not limited to, one side or portion (e.g., a left edge or a right edge) of the display panel 110. In one or more aspects, the gate driving circuit 120 may be located in, and/or electrically connected to, but not limited to, two sides or portions (e.g., a left edge and a right edge) of the display panel 110 or at least two of four sides or portions (e.g., an upper edge, a lower edge, the left edge, and the right edge) of the display panel 110 according to driving schemes, panel design schemes, or the like.

Each gate driver integrated circuit GDIC may be connected to a pad, such as a bonding pad, of the display panel 110 by a tape-automated-bonding (TAB) technique or a chip-on-glass (COG) technique, or be directly disposed in the display panel 110 by a gate-in-panel (GIP) technique. In one or more aspects, the one or more gate driver integrated circuits GDIC may be integrated into a circuitry or a circuit block of the display panel 110. In one or more aspects, each gate driver integrated circuit GDIC may be mounted on a film connected to display panel 110 by a chip-on-film (COF) technique.

The data driving circuit 130 can receive image data from the controller 140 and convert the received image data into analog data voltages. The data driving circuit 130 can output the data voltages to data lines DL according to timings at which scan signals delivered through gate lines GL are applied, and enable subpixels SP to emit light at luminance corresponding to the image data.

The data driving circuit 130 may include one or more source driver integrated circuits SDIC.

Each source driver integrated circuit SDIC may include a shift register, a latch circuit, a digital to analog converter, an output buffer, and the like.

Each source driver integrated circuit SDIC may be connected to a pad, such as a bonding pad, of the display panel 110 by the tape-automated-bonding (TAB) technique or the chip-on-glass (COG) technique, or be directly disposed in the display panel 110. In one or more aspects, the one or more source driver integrated circuits SDIC may be integrated into a circuitry or a circuit block of the display panel 110. In one or more aspects, each source driver integrated circuit SDIC may be implemented by the chip on film (COF) technique. In this implementation, each source driver integrated circuit SDIC may be mounted on a film connected to the display panel 110, and be electrically connected to the display panel 110 through lines on the film.

The controller 140 can provide several control signals to the gate driving circuit 120 and the data driving circuit 130, and control operations of the gate driving circuit 120 and the data driving circuit 130.

The controller 140 may be mounted on a printed circuit board (PCB), a flexible printed circuit (FPC), and/or the like, and be electrically connected to the gate driving circuit 120 and the data driving circuit 130 through the printed circuit board (PCB), flexible printed circuit (FPC), and/or the like.

The controller 140 can enable the gate driving circuit 120 to output a scan signal according to a timing processed in each frame, convert image data input from an external source, such as an external device, a network, a host system, and/or the like, to a data signal form used in the data driving circuit 130, and then output image data resulted from the converting to the data driving circuit 130.

The controller 140 can receive, in addition to image data, several types of timing signals including a vertical synchronous signal VSYNC, a horizontal synchronous signal HSYNC, an input data enable signal DE, a clock signal CLK, and the like from other devices or systems (e.g. a host system 150).

The controller 140 can generate several types of control signals using the several types of timing signals received from the other devices or systems and output the generated signals to the gate driving circuit 120 and the data driving circuit 130.

In one or more aspects, to control the gate driving circuit 120, the controller 140 can output several types of gate control signals GCS including a gate start pulse GSP, a gate shift clock GSC, a gate output enable signal GOE, and the like.

The gate start pulse GSP may be used for controlling an operation start timing of one or more gate driver integrated circuits GDIC included in the gate driving circuit 120. The gate shift clock GSC may be a clock signal commonly inputted to one or more gate driver integrated circuits GDIC, and be used for controlling a shift timing of a scan signal. The gate output enable signal GOE may be used for indicating timing information of one or more gate driver integrated circuits GDIC.

In one or more aspects, to control the data driving circuit 130, the controller 140 can output several types of data control signals DCS including a source start pulse SSP, a source sampling clock SSC, a source output enable (SOE) signal, and the like.

The source start pulse SSP may be used for controlling a data sampling start timing of one or more source driver integrated circuits SDIC included in the data driving circuit 130. The source sampling clock SSC may be a clock signal for controlling a sampling timing of data in each source driving integrated circuit SDIC. The source output enable signal SOE may be used for controlling an output timing of the data driving circuit 130.

The display device 100 may further include a power management integrated circuit for providing several types of voltages or currents to the display panel 110, the gate driving circuit 120, the data driving circuit 130, and the like, or for controlling the several types of voltages or currents to be provided.

Each subpixel SP may be defined by intersections of one or more gate lines GL and one or more data lines DL. Liquid crystals or a light emitting element according to types of display devices may be disposed in each subpixel SP.

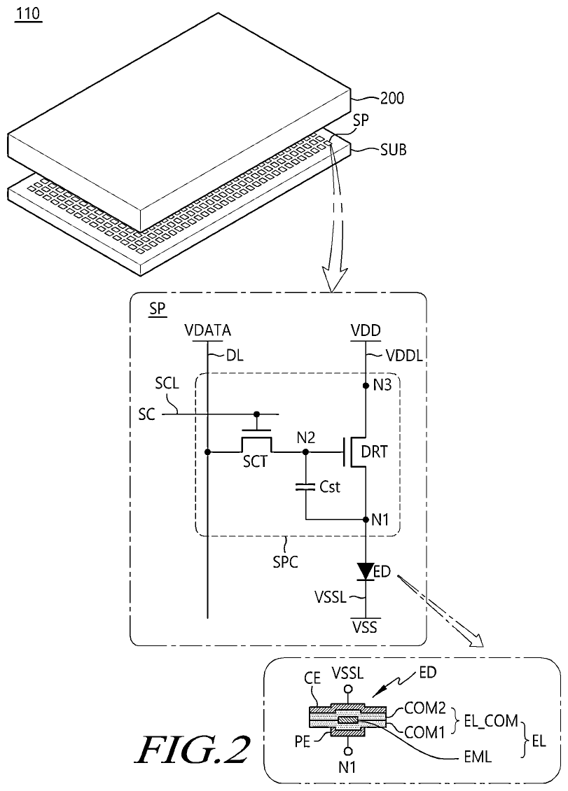

FIG. 2 illustrates an example configuration of the display panel 110 according to aspects of the present disclosure.

Referring to FIG. 2, in one or more example embodiments, the display panel 110 may include a substrate SUB on which a plurality of subpixels SP are disposed, and an encapsulation layer 200 over the substrate SUB. The encapsulation layer 200 may also be referred to as an encapsulation substrate or an encapsulation stack.

Referring to FIG. 2, in an example where the display device 100 is a self-emission display device, each of the plurality of subpixels SP disposed on the substrate SUB may include a light emitting element ED and a subpixel circuit SPC for driving the light emitting element ED.

Referring to FIG. 2, the subpixel circuit SPC may include a plurality of pixel driving transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of pixel driving transistors may include a driving transistor DRT for driving the light emitting element ED and a scan transistor SCT configured to be turned on or off according to a scan signal SC.

The driving transistor DRT can supply a driving current to the light emitting element ED.

The scan transistor SCT may be configured to control an electrical state of a corresponding node (e.g., a second node N2) in the subpixel circuit SPC or to control the state or operation of the driving transistor DRT.

The at least one capacitor may include a storage capacitor Cst configured to maintain a constant voltage during a display frame or a certain period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, common driving voltages including a first common driving voltage VDD and a second common driving voltage VSS may be applied to the one or more subpixels SP.

Each light emitting element ED may include a pixel electrode PE, an intermediate layer EL, and a common electrode CE. The intermediate layer EL may be disposed between the pixel electrode PE and the common electrode CE.

In an example where the light emitting element ED is an organic light emitting element such as an organic light emitting diode (OLED), the intermediate layer EL may include an emission layer EML and a common intermediate layer EL_COM. The common intermediate layer EL_COM may include a first common intermediate layer COM1 and a second common intermediate layer COM2. The first common intermediate layer COM1 may be disposed between the pixel electrode PE and the emission layer EML and may include at least one layer (e.g., an organic layer). The second common intermediate layer COM2 may be disposed between the emission layer EML and the common electrode CE and may include at least one layer (e.g., an organic layer).

In one or more aspects, the emission layer EML may be disposed in each of a plurality of subpixels SP, or be commonly disposed in all or some of the plurality of subpixels SP. The common intermediate layer EL_COM may be commonly disposed in all or some of the plurality of subpixels SP.

The emission layer EML may be disposed in each light emitting area, and the common intermediate layer EL_COM may be commonly disposed across a plurality of light emitting areas and a non-light emitting area.

The pixel electrode PE may be an electrode disposed in each subpixel SP, and the common electrode CE may be an electrode commonly disposed in all or some of the plurality of subpixels SP.

For example, the pixel electrode PE may be an anode and the common electrode CE may be a cathode. In another example, the pixel electrode PE may be the cathode and the common electrode CE may be the anode. Hereinafter, discussions are provided based on examples where the pixel electrode PE is an anode and the common electrode CE is a cathode.

In one or more aspects, the first common intermediate layer COM1 of the common intermediate layer EL_COM may include a hole injection layer HIL, a hole transport layer HTL, and the like. The second common intermediate layer COM2 of the common intermediate layer EL_COM may include an electron transport layer ETL, an electron injection layer EIL, and the like.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

In one or more aspects, the common electrode CE may be electrically connected to a second common driving voltage line VSSL. The second common driving voltage VSS, which is a type of common driving voltage, may be applied to the common electrode CE through the second common driving voltage line VSSL. The pixel electrode PE may be electrically connected directly or indirectly (via another transistor) to a first node N1 of the corresponding driving transistor DRT of each subpixel SP. Herein, the second common driving voltage VSS may also be referred to as a base voltage VSS, and the second common driving voltage line VSSL may be referred to as a base voltage line VSSL.

Each light emitting element ED may be configured by overlapping of a corresponding pixel electrode PE, a corresponding emission layer EML in the common intermediate layer EL, and a corresponding portion of the common electrode CE. A corresponding light emitting area may be formed by each light emitting element ED. For example, a corresponding light emitting area of each light emitting element ED may be configured by an area in which a corresponding pixel electrode PE, a corresponding emission layer EML in the common intermediate layer EL, and a corresponding portion of the common electrode CE overlap with each other.

In one or more aspects, the light emitting element ED may be an organic light emitting diode (OLED), an inorganic material-based light emitting diode (LED), or a quantum dot (QD) light emitting element. In an example where the light emitting element ED is an organic light emitting diode (OLED), the intermediate layer EL included in the light emitting element ED may be a layer including an organic material.

The driving transistor DRT may be a transistor configured to supply a driving current to the light emitting element ED. The driving transistor DRT may be connected between a first common driving voltage line VDDL and the light emitting element ED.

The driving transistor DRT may include a first node N1, a second node N2, and a third node N3. The first node N1 may be electrically connected to the light emitting element ED, data signals VDATA may be applied to the second node N2, and the first common driving voltage VDD delivered through the first common driving voltage line VDDL may be applied to the third node N3.

In the driving transistor DRT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DRT are source, gate, and drain nodes, respectively. However, example embodiments of the present disclosure are not limited thereto.

The scan transistor SCT included in the subpixel circuit SPC illustrated in FIG. 2 may be a switching transistor for allowing a data signal VDATA, which is an image signal, to be supplied to the second node N2, which is the gate node of the driving transistor DRT.

The scan transistor SCT can be turned on or turned off by a scan signal SC, which is a type of gate signal, carried through a scan signal line SCL, which is a type of gate line GL, and control an electrical connection between the second node N2 of the driving transistor DRT and a data line DL. The drain electrode or source electrode of the scan transistor SCT may be electrically connected to the data line DL. The source electrode or drain electrode of the scan transistor SCT may be electrically connected to the second node N2 of the driving transistor DRT. The gate electrode of the scan transistor SCT may be electrically connected to the scan signal line SCL.

The storage capacitor Cst may be electrically connected between the first node N1 and the second node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

In one or more aspects, the storage capacitor Cst may be an external capacitor intentionally designed to be located outside of the driving transistor DRT, other than an internal capacitor, such as a parasitic capacitor (e.g., a Cgs or a Cgd), that may be formed between the first node N1 and the second node N2 of the driving transistor DRT.

Each of the driving transistor DRT and the scan transistor SCT may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can be increased, and a corresponding aperture ratio can be increased.

In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2TIC structure”), and in some implementations, may further include one or more transistors, or further include one or more capacitors.

The types and number of gate signals supplied to a subpixel SP, and/or the types and number of gate lines connected to the subpixel SP may vary depending on a structure of a corresponding subpixel circuit SPC. The types and number of common driving voltages may vary depending on a structure of a corresponding subpixel circuit SPC.

Since circuit elements (in particular, a light emitting element ED implemented with an organic light emitting diode including an organic material) included in each subpixel SP are vulnerable to external moisture or oxygen, an encapsulation layer 200 may be disposed in the display panel 110 to prevent external moisture or oxygen from penetrating into such circuit elements. The encapsulation layer 200 may be disposed in various shapes or configurations to prevent light emitting elements ED from contacting moisture or oxygen.

In one or more aspects, the display device 100 may be configured to have an extremely narrow bezel structure in which the non-display area NDA of the display panel 110 is configured to have a very small size.

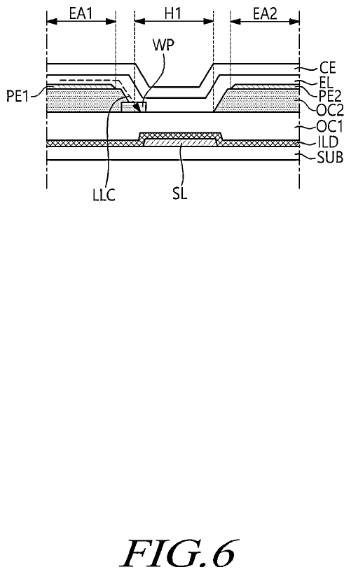

FIG. 6 is an example cross-sectional view of the display device 100 according to aspects of the present disclosure.

Referring to FIG. 6, in one or more example embodiments, the display device 100 may include a substrate SUB, a signal line SL, an interlayer insulating layer ILD, a first protective layer OC1, a second protective layer OC2, a first electrode PE, a common intermediate layer EL, a second electrode CE, and a wall pattern WP.

The substrate SUB may include, for example, an insulating material such as glass, plastic, crystal, or the like, but example embodiments of the present disclosure are not limited thereto. In an example where the substrate SUB includes organic polymers, the organic polymers may be, for example, polyethylene terephthalate (PET), polyethylene naphthalate (PEN), polyimide, polyether sulfone, or the like. The substrate SUB or a material included in the substrate SUB may be selected considering mechanical strength, thermal stability, transparency, surface smoothness, ease of handling, waterproofness, and the like.

The substrate SUB may include a display area allowing an image to be displayed so that users can recognize the image, and a non-display area corresponding to the remaining area except for the display area. A plurality of light emitting elements such as organic light emitting diodes may be disposed in the display area, and one or more pads configured to pass one or more electrical signals from a power supply (not shown) or a signal generator (not shown) to the display area may be disposed in the non-display area.

Thin film transistors (not shown) directly or electrically connected with various signal lines SL may be disposed in the display area of the substrate SUB. At least one of the thin film transistors may be electrically connected to a corresponding organic light emitting element ED.

The thin film transistors may include a driving thin film transistor for controlling the organic light emitting element ED and a switching thin film transistor for switching the driving thin film transistor.

Each thin film transistor may include a semiconductor layer, a gate electrode, a source electrode, and a drain electrode. The semiconductor layer may include a semiconductor material and serve as an active layer of the thin film transistor. The semiconductor layer may include an inorganic semiconductor material or an organic semiconductor material.

A gate insulating layer may be disposed on the semiconductor layer. The gate insulating layer may cover the semiconductor layer. The gate insulating layer may include at least one of an organic insulating material and an inorganic insulating material.

The gate electrode may be disposed on the gate insulating layer. The gate electrode may be configured to cover an area corresponding to a channel region of the semiconductor layer.

The source electrode and the drain electrode may be disposed on the interlayer insulating layer ILD on the gate insulating layer. The drain electrode may contact a drain region of the semiconductor layer through contact holes formed in the gate insulating layer and the interlayer insulating layer ILD, and the source electrode may contact a source region of the semiconductor layer through contact holes formed in the gate insulating layer and the interlayer insulating layer ILD.

The first protective layer OC1 and the second protective layer OC2 may be disposed on the source electrode, the drain electrode, and the interlayer insulating layer ILD. The first protective layer OC1 may serve as a protective layer for protecting the thin film transistor and also serve as a planarization layer for flattening the top of the thin film transistor. The second protective layer OC2 may serve to extract light or determine paths of light.

The second protective layer OC2 may include a first opening H1, and at least a portion of the first protective layer OC1 may be exposed by the first opening H1.

An organic light emitting element ED may be disposed on at least a portion of the second protective layer OC2. The organic light emitting element ED may include first electrodes (PE1 and PE2), the common intermediate layer EL disposed on the first electrodes (PE1 and PE2), and the second electrode CE disposed on the common intermediate layer EL.

The first electrodes (PE1 and PE2) may be a pixel electrode or an anode. The first electrodes (PE1 and PE2) may be a transmissive electrode, a semi-transmissive electrode, or a reflective electrode. The first electrodes (PE1 and PE2) may include a conductive compound containing a metal, a metal alloy, or a metal oxide. The first electrodes (PE1 and PE2) may include a transparent metal oxide, for example, indium tin oxide (ITO), indium zinc oxide (IZO), zinc oxide (ZnO), or indium tin zinc oxide (ITZO). The first electrodes (PE1 and PE2) may include Ag, Mg, Cu, Al, Pt, Pd, Au, Ni, Nd, Ir, Cr, Li, Ca, LiF/Ca, LiF/Al, Mo, Ti, or a compound or mixture (for example, a mixture of Ag and Mg) thereof. In one or more aspects, the first electrodes (PE1 and PE2) may have a structure configured with multiple layers including a reflective layer or a semi-transmissive layer including one or more of the forgoing materials and a transparent conductive layer including indium tin oxide (ITO), indium zinc oxide (IZO), zinc oxide (ZnO), indium tin zinc oxide (ITZO), or the like.

The second electrode CE may be a common electrode or a cathode. The second electrode CE may be a transmissive electrode, a semi-transmissive electrode, or a reflective electrode. The second electrode CE may include a conductive compound containing a metal, a metal alloy, or a metal oxide. The second electrode CE may include a transparent metal oxide, for example, indium tin oxide (ITO), indium zinc oxide (IZO), zinc oxide (ZnO), or indium tin zinc oxide (ITZO). The second electrode CE may include Ag, Mg, Al, Pt, Pd, Au, Ni, Nd, Ir, Cr, Li, Ca, LiF/Ca, LiF/Al, Mo, Ti, or a compound or mixture (for example, a mixture of Ag and Mg) thereof. In one or more aspects, the second electrode CE may have a structure configured with multiple layers including a reflective layer or a semi-transmissive layer including one or more of the forgoing materials and a transparent conductive layer including indium tin oxide (ITO), indium zinc oxide (IZO), zinc oxide (ZnO), indium tin zinc oxide (ITZO), or the like.

The first electrodes (PE1 and PE2) may be a reflective electrode, and the second electrode CE may be a semi-transmissive electrode or a transmissive electrode.

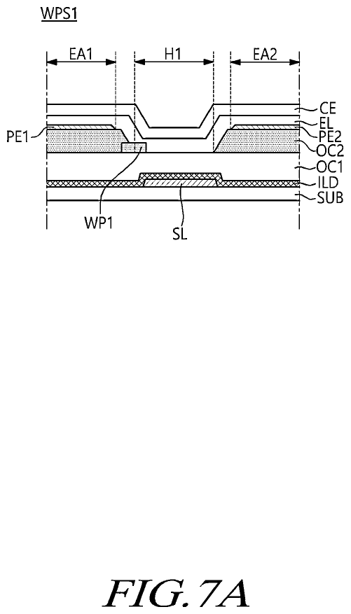

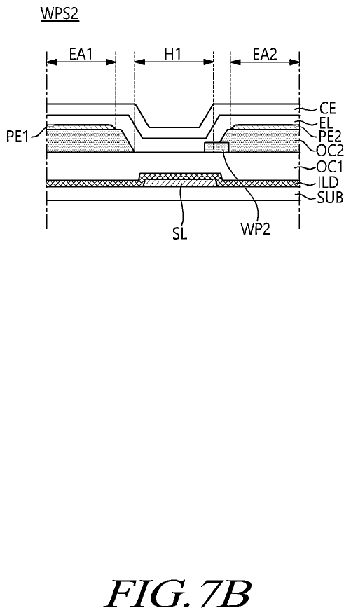

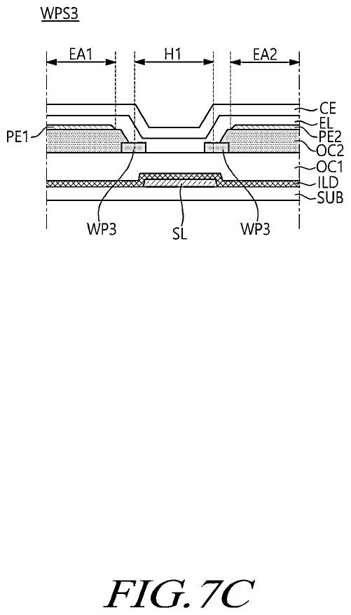

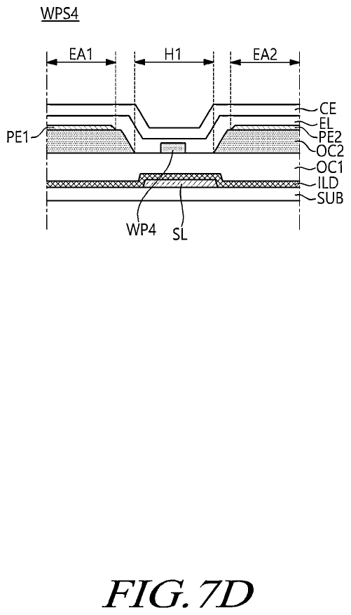

Referring to FIG. 6, the wall pattern WP may be disposed on the first protective layer OC1 and may be located at a boundary or inside of the first opening H1 formed in the second protective layer OC2. For example, a base voltage, which is applied to the second electrode CE, may be applied to the wall pattern WP1. In one or more aspects, the wall pattern WP1 may be a ground pattern. FIGS. 6 and 7A illustrate that the wall pattern WP1 is disposed at a side portion or a boundary of the first opening H1, but example embodiments of the present disclosure are not limited thereto. For example, a wall pattern WP may be disposed at different locations as illustrated in examples of FIGS. 7B to 7D. Therefore, in one embodiment, a light emitting element of a first subpixel may be disposed on a part of the second protective layer OC2 and a light emitting element of a second subpixel may be disposed on the another part of the second protective layer. The wall pattern WP may be disposed on the first protective layer OC1, and at least a portion of the wall pattern WP may be covered by the second protective layer OC2 or may be disposed on a portion of the first protective layer OC1.

In one or more aspects, the display device may include top-emission organic light emitting elements ED. However, example embodiments of the present disclosure are not limited thereto. For example, the display device may include bottom-emission organic light emitting elements ED.

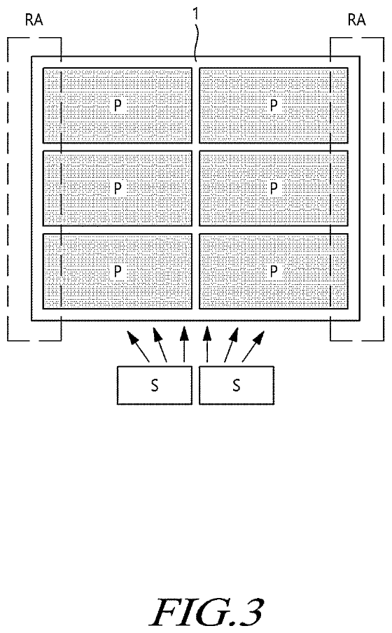

FIG. 3 is an example plan view schematically illustrating a deposition process for forming light emitting elements according to aspects of the present disclosure.

Referring to FIG. 3, a plurality of panel areas may be defined in a base substrate 1. For example, a plurality of display panels P (hereinafter, each display panel P may be the display panel 110 of FIGS. 1 and 2) may be arranged on the base substrate 1. Although FIG. 3 illustrates panel areas corresponding to six display panels P, but example embodiments of the present disclosure are not limited thereto.

After a deposition process is performed to form light emitting elements ED in each of the plurality of display panels P, a scribing process may be performed to separate the plurality of display panels P from each other.

A plurality of subpixels (e.g., each of which may be the subpixel SP of FIG. 2) may be disposed in each of the plurality of display panels P.

A respective display area may be defined in each of the plurality of panel areas. Thus, the plurality of subpixels SP may be disposed in each display area. For example, the plurality of subpixels SP may be configured with gate lines, data lines, thin film transistors, pixel electrodes, and the like.

Referring to FIG. 3, the display panels may be formed using deposition equipment. The deposition equipment may include a deposition chamber (not shown), a deposition source S disposed inside of the deposition chamber, and a mask assembly (not shown) disposed inside of the deposition chamber. The mask assembly can support a base substrate 1. The deposition chamber may be set to operate in a vacuum as a deposition condition. The deposition source S can evaporate a deposition material such as an inorganic material in the form of vapor.

Although not shown in FIG. 3, the deposition equipment may further include a jig or robot arm for holding the mask assembly. In one or more aspects, the deposition equipment may further include additional machinery to implement an in-line system.

For example, an insulating layer may be formed in the display panels using the deposition equipment. For example, a conductive layer or a semiconductor layer may be formed in the display panels, and then, be patterned, using the deposition equipment. Forming the conductive layer and semiconductor layer according to example embodiments of the present disclosure is not limited thereto.

In one or more aspects, an emission layer may be formed on the display panel using another deposition equipment. The deposition equipment for forming such an emission layer may include mask assemblies including masks. A plurality of openings may be defined in each of the masks, and the openings may be uniformly disposed. Different types of emission layers may be formed using a plurality of types of masks with different opening patterns.

After light emitting elements are formed in each display panel on the base substrate 1, the base substrate 1 may be cut into individual display panels using a cutting wheel or the like, and thereby, separated display panels may be obtained.

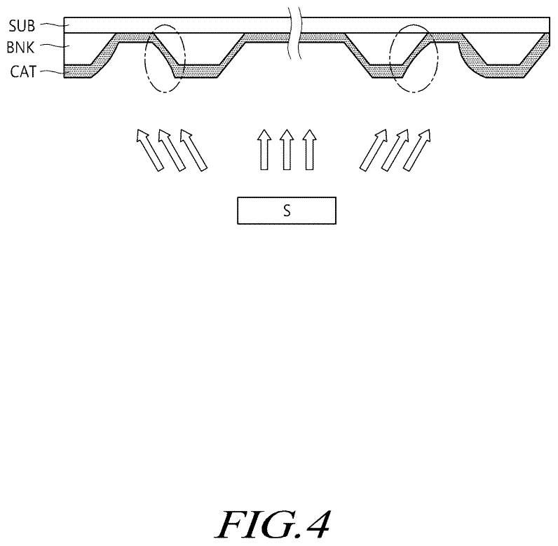

FIG. 4 is a cross-sectional view illustrating an example where a deposition layer (or a deposited material) does not have a uniform thickness depending on relative locations of a deposition source and a display panel when a deposition process is performed for forming light emitting elements on a base substrate according to aspects of the present disclosure.

Referring to FIG. 4, it can be seen that the thickness of the deposited material is uneven, that is, the deposited material is not uniformly formed, depending on locations of the deposited material.

Thus, in a situation where by using a deposition source S, a deposition material is deposited in the form of deposition vapor to form an emission layer or a cathode layer, the thickness of the deposited material may not be uniform depending on relative locations of the deposition source S and the emission layer or the cathode layer deposited in a display panel P.

For example, in the case of a display panel P located in a vertical direction facing the deposition source S, since deposition vapor is relatively evenly sprayed on a layer to be deposited (e.g., the emission layer or the cathode layer), the deposited material may be formed with a uniform thickness regardless of locations.

In the case of a display panel P located in a diagonal direction to the deposition source S rather than facing vertically to the deposition source S, since an element previously formed in the display panel P may act as an obstacle to the spraying of deposition vapor, the thickness of the deposited material may be uneven depending on locations, or there may occur a situation where the deposited material is disconnected.

Referring to FIGS. 3 and 4, as described above, due to relative locations of the deposition source S and the display panel P or the location of a layer to be deposited in the display panel P, an area at which the resulting deposited material has a thickness less than normally deposited material may be defined as a risk area RA.

For example, in such a risk area RA, as a deposition thickness of an electrode layer (e.g., a cathode) is reduced or disconnected, oxygen or moisture may penetrate into the reduced portion or disconnected portion, and thereby, a corresponding light emitting element ED may be shrunk.

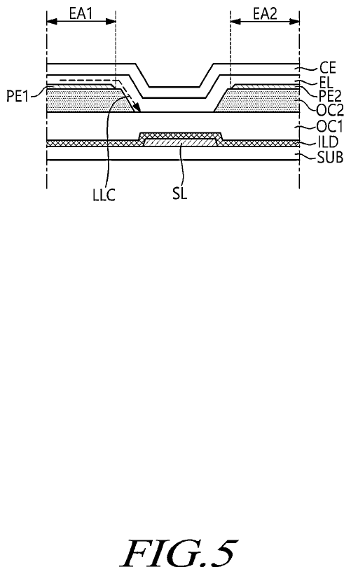

In another example, in the risk area RA, as a deposition thickness of a cathode layer is reduced or disconnected, lateral leakage current LLC may flow through a common intermediate layer EL under the cathode layer, as shown in FIG. 5.

In further another example, when an inclined surface of a bank has a great height or is formed at a great angle to a flat portion of the bank, a deposition thickness of the cathode disposed on the bank may be reduced or disconnected.

For example, as an amount of current flowing through a green subpixel is relatively greater than an amount of current flowing through a blue or red pixel, even when the green subpixel is not intended to emit light, there may occur a situation where the green subpixel emits light due to lateral leakage current.

To address these issues, in one or more example embodiments, as shown in FIG. 6, a respective wall pattern WP may be disposed on the first protective layer OC in each display panel P considering relative locations of a deposition source S and each display panel P. Thereby, a deposition thickness of a common intermediate layer EL or a cathode layer CE formed in each display panel during a deposition process can be uniformly formed regardless of locations.

In addition, referring to FIG. 6, as lateral current leaking through the common intermediate layer EL is discharged through the wall pattern WP, which may be a ground pattern, leakage current flowing along the common intermediate layer EL of a corresponding subpixel can be prevented from flowing into another adjacent subpixel. To obtain there results, the wall pattern WP may include a metal or metal pattern.

Hereinafter, forming the wall pattern WP is described in detail with reference to FIGS. 7 to 9.

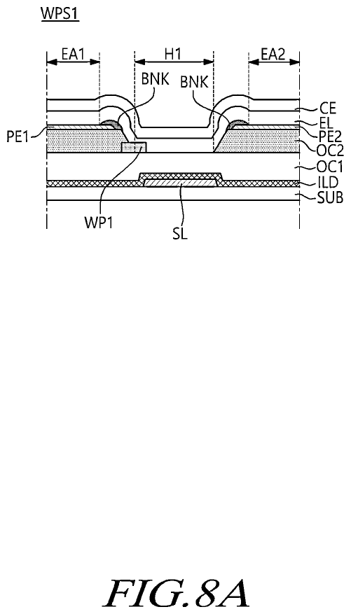

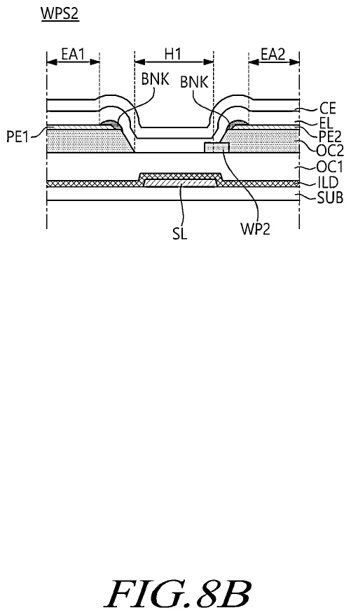

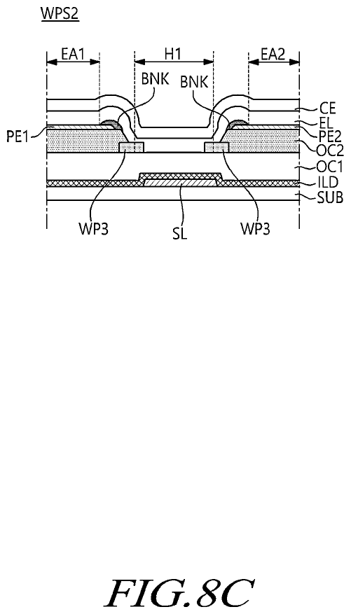

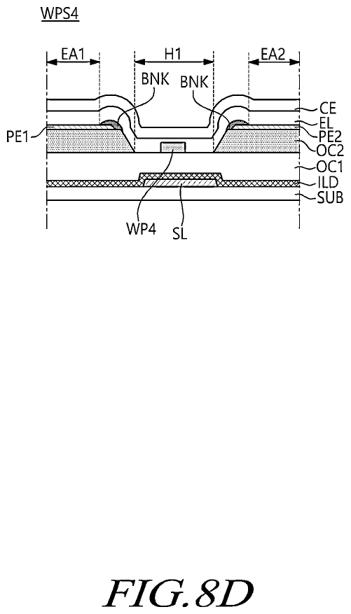

FIGS. 7A to 7D and FIGS. 8A to 8D illustrate example cross-sections of the display panel according to aspects of the present disclosure.

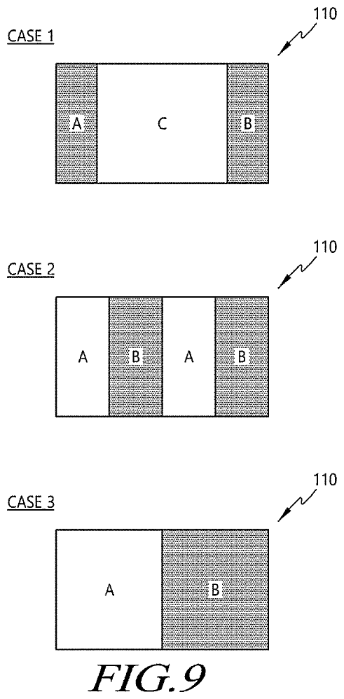

FIG. 9 is an example plan view illustrating that wall patterns WP are disposed in different locations in the display panel according to aspects of the present disclosure.

Referring to FIGS. 7A to 8D, in one or more example embodiments, the display panel P may include a substrate SUB, a first protective layer OC1 over the substrate SUB, a second protective layer OC2 disposed on the first protective layer OC1 and having a first opening, a plurality of first electrodes (PE1 and PE2) disposed on the second protective layer OC2, and a wall pattern WP1 disposed on the first protective layer OC1 and disposed at a boundary, or inside, of the first opening. The display panel P may further include a common intermediate layer EL covering the plurality of first electrodes (PE1 and PE2), the second protective layer OC2, and a portion of the first protective layer OC1 exposed by the first opening, and a second electrode CE disposed on the common intermediate layer EL. The manufacturing method and materials for each layer have been previously described with reference to FIG. 6.

For example, a display panel P may be provided with a wall pattern WP disposed in a location determined depending on a relative location of a deposition source S and the display panel P.

In one or more aspects, a first wall pattern WP1, a second wall pattern WP2, a third wall pattern WP3, and/or a fourth wall pattern WP4, which may be disposed in different locations and/or have different configurations, may be disposed in the display panel P. This will be described in detail below.

As shown in FIG. 7A, in one or more aspects, the display panel P may include a first wall pattern WP1 located in a portion of a first boundary of the first opening H1.

For example, the first wall pattern WP1 may be disposed in the portion of the first boundary of the first opening H1 adjacent to a first emission area EA1 and on the first protective layer OC1, as shown in the cross-sectional view of FIG. 7A. At least a portion of the first wall pattern WP1 may be covered by the second protective layer OC2 or the common intermediate layer EL. In one embodiment, a first subpixel may be disposed left of a second subpixel, and the part of the second protective layer OC2 covers at least a portion of the wall pattern WP.

As shown in FIG. 7B, in one or more aspects, the display panel P may include a second wall pattern WP2 located in a portion of a second boundary opposite to the first boundary of the first opening H1.

For example, the second wall pattern WP2 may be disposed in the portion of the second boundary of the first opening H1 adjacent to a second emission area EA2 and on the first protective layer OC1, as shown in the cross-sectional view of FIG. 7B. At least a portion of the second wall pattern WP2 may be covered by the second protective layer OC2 or the common intermediate layer EL. In one embodiment, a second subpixel may be disposed right of a first subpixel, and the another part of the second protective layer OC2 covers at least a portion of the wall pattern WP.

As shown in FIG. 7C, in one or more aspects, the display panel P may include third wall patterns WP3 disposed in respective portions of the first boundary and the second boundary of the first opening H1 and disposed on the first protective layer OC1.

For example, the third wall patterns WP3 may be respectively disposed in the portion of the first boundary of the first opening H1 adjacent to the first emission area EA1 and in the portion of the second boundary of the first opening H1 adjacent to the second emission area EA2, as shown in the cross-sectional view of FIG. 7C. In one embodiment, a part of the second protective layer OC2 covers at least a portion of the wall pattern WP and another part of the second protective layer OC2 covers at least a portion of a second wall pattern WP.

Thus, the third wall patterns WP3 may be a configuration including both the first wall pattern WP1 and the second wall pattern WP2.

As shown in FIG. 7D, in one or more aspects, the display panel P may include a fourth wall pattern WP4 located inside of the first opening H1.

For example, the fourth wall pattern WP4 may be disposed at the center of the first opening H1 and on the first protective layer OC1, as shown in the cross-sectional view of FIG. 7D. The fourth wall pattern WP4 may be covered by the common intermediate layer EL. The fourth wall pattern WP4 may disposed on a portion of the first protective layer OC1 between a part and another part of the second protective layer OC2.

FIGS. 8A to 8D illustrate example cross-sections of the display panel including a respective wall pattern according to aspects of the present disclosure. The configurations of FIGS. 8A to 8D may be the same or substantially the same as the configurations of FIGS. 7A to 7D, except that a bank BNK is further disposed on at least a portion of the second protective layer OC2 and at least respective portions of the first electrodes (PE1 and PE2).

As shown in FIG. 8A, in one or more aspects, the display panel P may include a first wall pattern WP1 located in a portion of a first boundary of the first opening H1.

For example, the first wall pattern WP1 may be disposed in the portion of the first boundary of the first opening H1 adjacent to a first emission area EA1 and on the first protective layer OC1, as shown in the cross-sectional view of FIG. 8A. At least a portion of the first wall pattern WP1 may be covered by the second protective layer OC2 or the common intermediate layer EL.

As shown in FIG. 8B, in one or more aspects, the display panel P may include a second wall pattern WP2 located in a portion of a second boundary opposite to the first boundary of the first opening H1.

For example, the second wall pattern WP2 may be disposed in the portion of the second boundary of the first opening H1 adjacent to a second emission area EA2 and on the first protective layer OC1, as shown in the cross-sectional view of FIG. 8B. At least a portion of the second wall pattern WP2 may be covered by the second protective layer OC2 or the common intermediate layer EL.

As shown in FIG. 8C, in one or more aspects, the display panel P may include third wall patterns WP3 disposed in respective portions of the first boundary and the second boundary of the first opening H1 and disposed on the first protective layer OC1.

For example, the third wall patterns WP3 may be respectively disposed in the portion of the first boundary of the first opening H1 adjacent to the first emission area EA1 and in the portion of the second boundary of the first opening H1 adjacent to the second emission area EA2, as shown in the cross-sectional view of FIG. 8C.

Thus, the third wall patterns WP3 may be a configuration including both the first wall pattern WP1 and the second wall pattern WP2.

As shown in FIG. 8D, in one or more aspects, the display panel P may include a fourth wall pattern WP4 located inside of the first opening H1.

For example, the fourth wall pattern WP4 may be disposed at the center of the first opening H1 and on the first protective layer OC1, as shown in the cross-sectional view of FIG. 8D. The fourth wall pattern WP4 may be covered by the common intermediate layer EL.

FIG. 9 is an example plan view illustrating that a display area is divided into sub-areas in different locations in the display panel according to aspects of the present disclosure.

In Case 1, the display panel 110 may be divided into a first area A located on a first side of a central data line located in a central area of the display panel (or the display area) among a plurality of data lines, a second area B located on a second side opposite to the first side of the central data line, and a third area C between the first area A and the second area B.

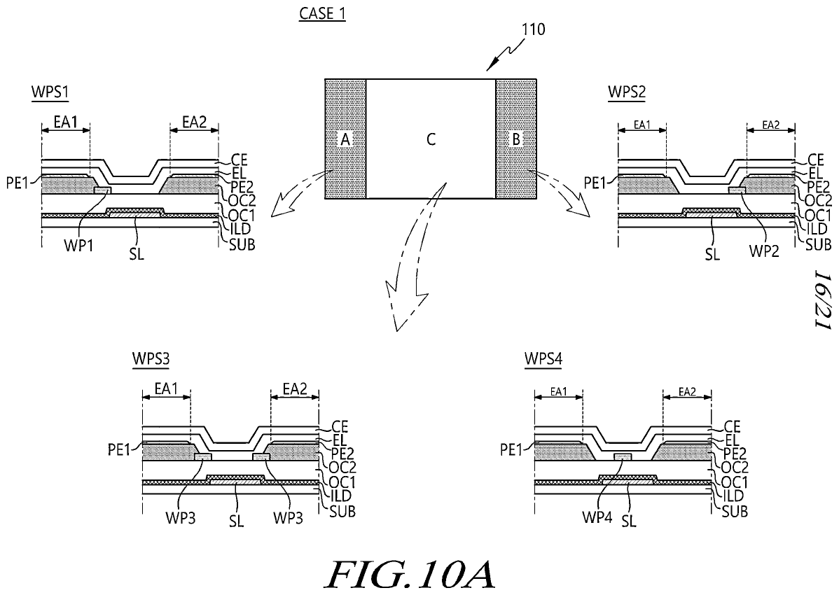

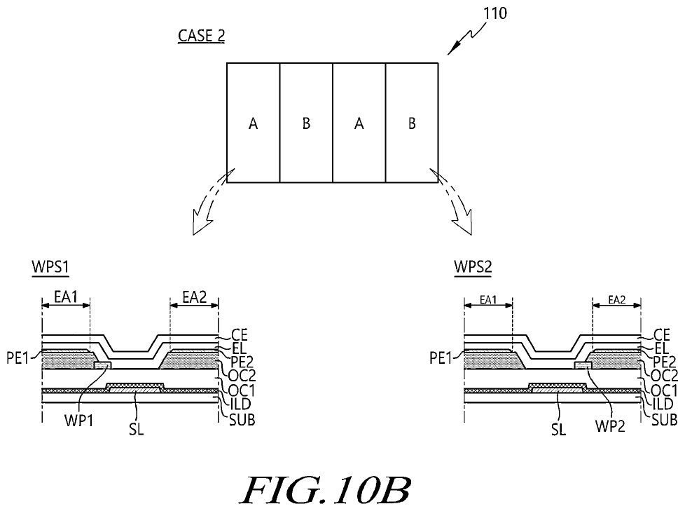

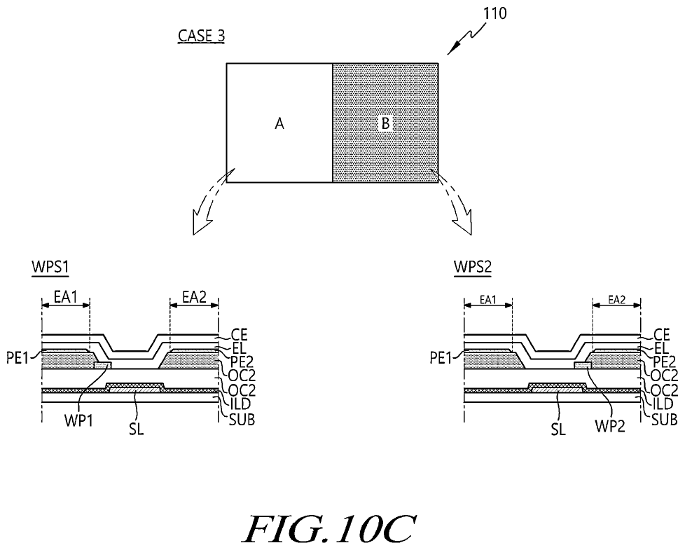

FIG. 10A is a cross-sectional view illustrating example locations of wall patterns disposed in the display area in Case 1 in the display panel according to aspects of the present disclosure.

Referring to FIG. 10A, in an example where the display panel 110 is divided into a first area A located on a first side of a central data line located in a central area of the display panel (or the display area) among a plurality of data lines, a second area B located on a second side opposite to the first side of the central data line, and a third area C between the first area A and the second area B, wall patterns may be disposed as follows: when a first opening H1 is located in the first area A, the display panel 110 may include a first wall pattern WP1; when the first opening H1 is located in the second area B, the display panel 110 may include a second wall pattern WP2; and when the first opening H1 is located in the third area C, the display panel 110 may include third wall patterns WP3 or a fourth wall pattern WP4.

Referring back to FIG. 9, in Case 2, display area of the display panel 110 may be divided into two areas located side by side on a first side of a central data line located in a central area of the display panel (or the display area) among a plurality of data lines, and two areas side by side located on a second side opposite to the first side of the central data line.

For example, Case 2 may be regarded as a structure in which as the third area C in Case 1 is divided in half with respect to the central data line, a first area A and a second area B located on right and left sides of the central data line are further disposed in the third area C, compared with Case 1.

Accordingly, in Case 2, the display panel 110 may be divided into a first area A, a second area B, another first area A, and another second area B in the horizontal direction from the left.

FIG. 10B is a cross-sectional view illustrating example locations of wall patterns disposed in the display area in Case 2 in the display panel according to aspects of the present disclosure.

Referring to FIG. 10B, in an example where the display panel 110 is divided into a left first area A, a left second area B, a right first area A, and a right second area B in the horizontal direction from the left, wall patterns may be disposed as follows: when a first opening H1 is located in the left first area A or the right first area A, the display panel 110 may include a first wall pattern WP1; and when the first opening H1 is located in the left second area B and the right second area B, the display panel 110 may include a second wall pattern WP2.

Referring back to FIG. 9, in Case 3, the display panel 110 may be divided into a first area A located on a first side of a central data line located in a central area of the display panel (or the display area) among a plurality of data lines, and a second area B located on a second side opposite to the first side of the central data line.

FIG. 10C is a cross-sectional view illustrating example locations of wall patterns disposed in the display area in Case 3 in the display panel according to aspects of the present disclosure.

Referring to FIG. 10C, in an example where the display panel 110 is divided into a first area A located on a first side of a central data line located in a central area of the display panel (or the display area) among a plurality of data lines, and a second area B located on a second side opposite to the first side of the central data line, wall patterns may be disposed as follows: when a first opening H1 is located in the first area A, the display panel 110 may include a first wall pattern WP1; and when the first opening H1 is located in the second area B, the display panel 110 may include a second wall pattern WP2.

To enable these examples to be implemented, as described above, the display device 100 may include a plurality of data lines extending in the column direction of the display panel 110, and the wall patterns WP may extend in the column direction.

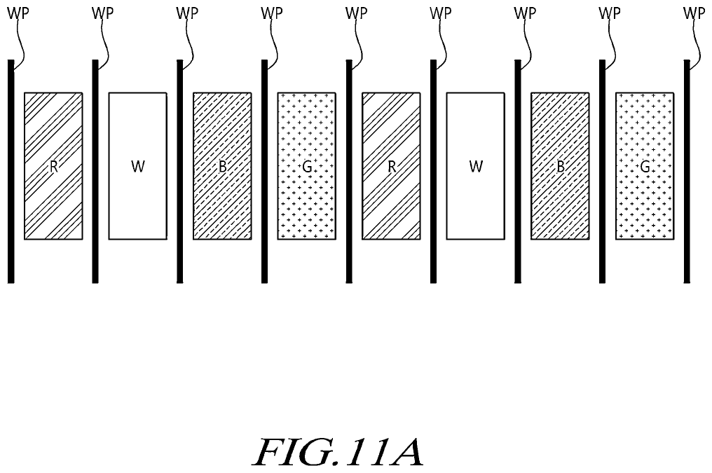

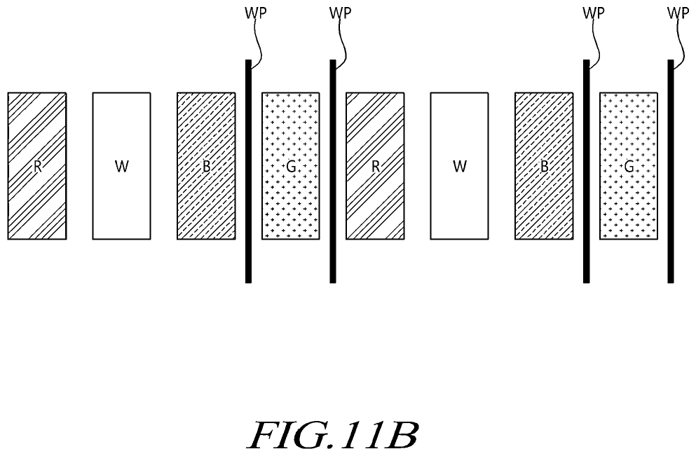

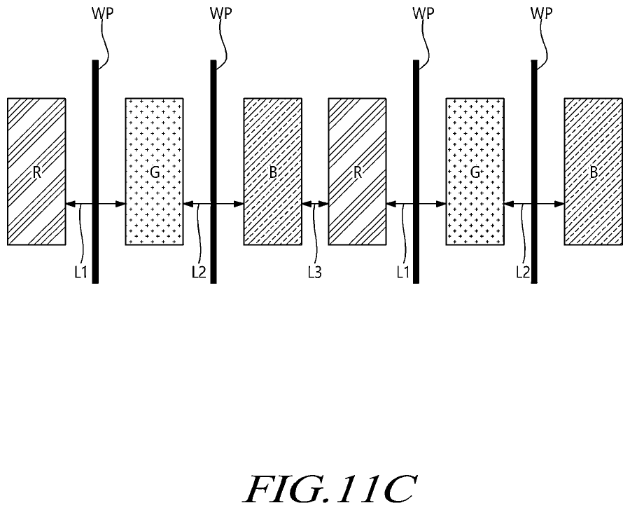

FIGS. 11A to 11C illustrate example wall patterns disposed between subpixels in the display panel according to aspects of the present disclosure.

Referring to FIG. 11A, in one or more example embodiments, a wall pattern may be disposed in each first opening H1 located between three or four subpixels included in one pixel. For example, each of the three or four subpixels can emit light of a different color. In one or more aspects, each of the four subpixels may emit red light, white light, blue light, and green light, and each of the three subpixels may emit red light, blue light, and green light. In the examples where a corresponding wall pattern WP is disposed in each first opening H between subpixels, lateral leakage current can be prevented with a high probability.

However, in these examples, there may be a disadvantage that the overall aperture ratio of the display panel may be reduced and the design margin may be insufficient.

To address these issues, as shown in FIG. 11B, at least one wall pattern WP may be disposed only in at least one first opening H1 located on at least one side of each green subpixel.

Thus, considering that an amount of current flowing through a green subpixel is relatively greater than an amount of current flowing through a blue or red subpixel, at least one wall pattern WP may be disposed only in at least one first opening H1 located on at least one side of each green subpixel.

For example, a red subpixel, a green subpixel, and a blue subpixel may be arranged in this order, and according to this arrangement, a plurality of red subpixels, a plurality of green subpixels, and a plurality of blue subpixels may be arranged in a predefined direction of the display panel 110.

Referring to FIG. 11C, in even examples where three subpixels are included in one pixel, at least one wall pattern WP may be disposed only in at least one first opening H1 located on at least one side of each green subpixel.

Referring to FIG. 11C, when a distance between a green subpixel and a red subpixel is a first distance L1, a distance between the green subpixel and a blue subpixel is a second distance L2, and a distance between the red subpixel and the blue subpixel is a third distance L3, the third distance L3 may be less than the first distance L1 and the second distance L2.

As in these implementations, by disposing a wall pattern only in a first opening H1 located on a side of a subpixel with the highest probability of lateral leakage current among subpixels, a reduction in the aperture ratio can be minimized and a sufficient design margin can be ensured.

Accordingly, a wall pattern may be disposed only in a first opening H1 located on the side of the green subpixel, and a distance between the remaining color subpixels may be set to have a value less than a distance between the green subpixel and an adjacent subpixel between which the first opening H1 containing the wall pattern is located. Thereby, the design margin can be reduced.

The example embodiments described above will be briefly described as follows.

According to the example embodiments of the present disclosure, a display device can be provided that includes a substrate including a display area allowing an image to be displayed and a non-display area outside of the display area, a first protective layer over the substrate, a second protective layer disposed on the first protective layer and having a first opening, a plurality of first electrodes disposed on the second protective layer, and a wall pattern disposed on the first protective layer and located at an boundary or inside of the first opening.

In one or more aspects, the wall pattern may include at least one of a first wall pattern located at a portion of a first boundary of the first opening, a second wall pattern located at a portion of a second boundary opposite to the first boundary of the first opening, third wall patterns respectively located at respective portions of the first and second boundaries of the first opening, and a fourth wall pattern located inside of the first opening.

In one or more aspects, the display area may include a first area located on a first side of a central data line located in a central area of the display area among a plurality of data lines, and a second area located on a second side opposite to the first side of the central data line, and when the first opening is located in the first area, the wall pattern may include the first wall pattern.

In one or more aspects, the display area may include a first area located on a first side of a central data line located in a central area of the display area among a plurality of data lines, and a second area located on a second side opposite to the first side of the central data line, and when the first opening is located in the second area, the wall pattern may include the second wall pattern.

In one or more aspects, the display area may include a first area located on a first side of a central data line located in a central area of the display area among a plurality of data lines, a second area located on a second side opposite to the first side of the central data line, and a third area between the first area and the second area, and when the first opening is located in the third area, the wall pattern may include the third wall patterns or the fourth wall pattern.

In one or more aspects, the display device may further include a common intermediate layer on the plurality of first electrodes, and a second electrode on the common intermediate layer, and the common intermediate layer may be configured to extend to the plurality of first electrodes on the second protective layer and the wall pattern.

For example, leakage current sourced from the common intermediate layer may flow through the wall pattern.

In one or more aspects, the wall pattern may be a ground pattern.

In one or more aspects, the display device may further include a common intermediate layer on the plurality of first electrodes, and a second electrode on the common intermediate layer, and a base voltage applied to the second electrode may be applied to the wall pattern.

In one or more aspects, the display device may further include a plurality of data lines extending in a column direction, and the wall pattern may extend in the column direction.

In one or more aspects, the display area may include a plurality of subpixels, and the wall pattern may be disposed between two adjacent subpixels among the plurality of subpixels.

In one or more aspects, the display area may include a red subpixel, a green subpixel, and a blue subpixel, and the wall pattern may be disposed on at least one side of one of the red subpixel, the green subpixel, and the blue subpixel.

In one or more aspects, the wall pattern may be disposed on at least one side of the green subpixel among the red subpixel, the green subpixel, and the blue subpixel.

In one or more aspects, leakage current sourced from the green subpixel may have a greater amount of current than leakage current sourced from each of the red subpixel and the blue subpixel.

In one or more aspects, the red subpixel, the green subpixel, and the blue subpixel may be disposed in this order, and when a distance between the green subpixel and the red subpixel is a first distance, a distance between the green subpixel and the blue subpixel is a second distance, and a distance between the red subpixel and the blue subpixel is a third distance, the third distance may be less than the first distance and the second distance.

In one or more aspects, the display device may further include a bank covering at least a portion of each of the plurality of first electrodes.

In one or more aspects, the bank overlaps with at least a portion of the wall pattern.

The above description has been presented to enable any person skilled in the art to make and use inventions, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. Although the exemplary embodiments have been described for illustrative purposes, a person skilled in the art will appreciate that various modifications and applications are possible without departing from the essential characteristics of the present disclosure. For example, the specific components of the exemplary embodiments may be variously modified. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims. The scope of protection of the present disclosure is to be construed according to the claims, and all technical ideas within the scope of the claims should be interpreted as being included in the scope of the present disclosure.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present disclosure.

What is claimed is:

1. A display device comprising:
a substrate comprising a display area for displaying an image and a non-display area outside of the display area;
a first protective layer over the substrate;
a second protective layer disposed on the first protective layer and having a first opening;
a plurality of first electrodes disposed on the second protective layer; and
a wall pattern disposed on the first protective layer and located at a boundary or inside of the first opening.

2. The display device of claim 1, wherein the wall pattern comprises at least one of a first wall pattern located at a portion of a first boundary of the first opening, a second wall pattern located at a portion of a second boundary opposite to the first boundary of the first opening, third wall patterns respectively located at respective portions of the first boundary and the second boundary of the first opening, and a fourth wall pattern located inside of the first opening.

3. The display device of claim 2, wherein the display area comprises a first area located on a first side of a central data line located in a central area of the display area among a plurality of data lines, and a second area located on a second side opposite to the first side of the central data line, and
wherein when the first opening is located in the first area, the wall pattern comprises the first wall pattern.

4. The display device of claim 2, wherein the display area comprises a first area located on a first side of a central data line located in a central area of the display area among a plurality of data lines, and a second area located on a second side opposite to the first side of the central data line, and
wherein when the first opening is located in the second area, the wall pattern comprises the second wall pattern.

5. The display device of claim 2, wherein the display area comprises a first area located on a first side of a central data line located in a central area of the display area among a plurality of data lines, a second area located on a second side opposite to the first side of the central data line, and a third area between the first area and the second area, and
wherein when the first opening is located in the third area, the wall pattern comprises the third wall patterns or the fourth wall pattern.

6. The display device of claim 1, further comprising:
a common intermediate layer on the plurality of first electrodes; and
a second electrode on the common intermediate layer,
wherein the common intermediate layer is configured to extend to the plurality of first electrodes on the second protective layer and the wall pattern.

7. The display device of claim 6, wherein leakage current sourced from the common intermediate layer flows through the wall pattern.

8. The display device of claim 1, wherein the wall pattern is a ground pattern.

9. The display device of claim 1, further comprising:
a common intermediate layer on the plurality of first electrodes; and
a second electrode on the common intermediate layer,
wherein a base voltage applied to the second electrode is applied to the wall pattern.

10. The display device of claim 1, further comprising: a plurality of data lines extending in a column direction,
wherein the wall pattern extends in the column direction.

11. The display device of claim 1, wherein the display area comprises a plurality of subpixels, and the wall pattern is disposed between two adjacent subpixels among the plurality of subpixels.

12. The display device of claim 1, wherein the display area comprises a red subpixel, a green subpixel, and a blue subpixel, and the wall pattern is disposed on at least one side of one of the red subpixel, the green subpixel, and the blue subpixel.

13. The display device of claim 12, wherein the wall pattern is disposed on at least one side of the green subpixel among the red subpixel, the green subpixel, and the blue subpixel.

14. The display device of claim 12, wherein leakage current sourced from the green subpixel has a greater amount of current than leakage current sourced from each of the red subpixel and the blue subpixel.

15. The display device of claim 12, wherein the red subpixel, the green subpixel, and the blue subpixel are disposed in this order, and when a distance between the green subpixel and the red subpixel is a first distance, a distance between the green subpixel and the blue subpixel is a second distance, and a distance between the red subpixel and the blue subpixel is a third distance, the third distance is less than the first distance and the second distance.

16. The display device of claim 1, further comprising: a bank covering at least a portion of each of the plurality of first electrodes.

17. The display device of claim 16, wherein the bank overlaps with at least a portion of the wall pattern.

18. A display device comprising:
a substrate;
a first protective layer on the substrate;
a second protective layer on the first protective layer, the second protective layer including a part and another part, wherein at least a portion of the first protective layer is exposed between the part and the another part of the second protective layer;
a first subpixel and a second subpixel on the substrate, wherein a light emitting element of the first subpixel is disposed on the part of the second protective layer and a light emitting element of the second subpixel is disposed on the another part of the second protective layer; and
a wall pattern disposed on the first protective layer, wherein at least a portion of the wall pattern is covered by the second protective layer or is disposed on the exposed portion of the first protective layer.

19. The display device of claim 18, wherein the first subpixel is disposed left of the second subpixel, and the part of the second protective layer covers at least a portion of the wall pattern.

20. The display device of claim 18, wherein the second subpixel is disposed right of the first subpixel, and the another part of the second protective layer covers at least a portion of the wall pattern.

21. The display device of claim 18, further comprising a second wall pattern, wherein the part of the second protective layer covers at least a portion of the wall pattern and the another part of the second protective layer covers at least a portion of the second wall pattern.

22. The display device of claim 18, further comprising a third subpixel and a fourth subpixel on the substrate and a second wall pattern disposed on the first protective layer,
wherein the first subpixel and the second subpixel is in a first region of the substrate, wherein the first subpixel is disposed left of the second subpixel and the wall pattern is closer to the first subpixel than the second subpixel, and
wherein the third subpixel and the fourth subpixel is in a second region of the substrate, wherein the fourth subpixel is disposed right of the third subpixel and the second wall pattern is closer to the fourth subpixel than the third subpixel.

23. The display device of claim 18, further comprising a third subpixel on the substrate, wherein at least one of the first subpixel and the second subpixel emits green light, and wherein there is no wall pattern disposed between the second subpixel and the third subpixel.

24. The display device of claim 18, further comprising a bank covering at least a portion of a first electrode of the light emitting element of the first subpixel.

25. The display device of claim 18, wherein the light emitting element of the first subpixel includes a first portion of an emission layer and the light emitting element of the second subpixel includes a second portion of the emission layer, and wherein the emission layer is disposed on the wall pattern.
